(19) United States
(12) Patent Application Publication
(10) Pub. No.: US 2012/0320541 A1
(43) Pub. Date: Dec. 20, 2012

(54) FLEXIBLE DISPLAY DEVICE AND CARD WITH DISPLAY FUNCTION USING THE SAME

(75) Inventor: Jung-Hsiu CHEN, Taoyuan County (TW)

(73) Assignee: AniCa Corporation, New Taipei City (TW)

(21) Appl. No.: 13/372,527

(22) Filed: Feb. 14, 2012

(30) Foreign Application Priority Data
Jun. 16, 2011 (TW) 100210928

(51) Int. Cl. H05K 7/06

(52) U.S. Cl. 361/749

(57) ABSTRACT

A flexible display device and a card with display function using the same are provided. The flexible display device comprises a multi-layer substrate and a display module. The multi-layer substrate comprises a patterned layer, a trace layer, an insulation layer and a intact copper foil. The insulation layer is disposed between the patterned layer and the trace layer. The trace layer is disposed between the insulation layer and the intact copper foil, such that the trace layer is protected by the intact copper foil. The display module is disposed on the patterned layer.

This application claims the benefit of Taiwan application Serial No. 100210928, filed Jun. 16, 2011, the subject matter of which is incorporated herein by reference.

### BACKGROUND OF THE INVENTION

1. Field of the Invention

The invention relates in general to a flexible display device and the card with display function using the same, and more particularly to a flexible display device adopting multi-layer substrate and a card with display function using the same.

2. Description of the Related Art

The conventional flexible display device comprises a substrate, a display module, an upper passivation film and a lower passivation film. The substrate has an upper surface and a lower surface, and comprises at least one patterned conductive layer and at least one insulation layer, wherein each insulation layer has a via hole, the patterned conductive layers are electrically connected through the via holes. The display module is disposed on the upper surface of the substrate. The upper passivation film encapsulates the entire display module. The lower passivation film covers the lower surface of the patterned conductive layer to avoid the moisture entering the substrate from the patterned conductive layer and the via hole and further damaging the substrate and the display module.

However, too many passivation films only incur more cost and deteriorate product competiveness.

### SUMMARY OF THE INVENTION

The invention is directed to a flexible display device and the card with display function using the same. In the part of the substrate of the flexible display device, the trace layer is disposed between the insulation layer and the intact copper foil, such that the trace layer can be protected by the intact copper foil to avoid the moisture damaging the display module of the flexible display device through the substrate.

According to one embodiment of the present invention, a flexible display device is provided. The flexible display device comprises a multi-layer substrate and a display module. The multi-layer substrate comprises a patterned layer, a first trace layer, a first insulation layer and a first intact copper foil. The first insulation layer is disposed between the patterned layer and the first trace layer. The display module is disposed on the patterned layer. The first trace layer is disposed between the first insulation layer and the first intact copper foil, such that the first trace layer is protected by the first intact copper foil.

According to an alternate embodiment of the present invention, a card with display function is provided. The card with display function comprises a flexible display device and an enveloping layer. The flexible display device comprises a multi-layer substrate and a display module. The multi-layer substrate comprises a patterned layer, the first insulation layer, a first trace layer and a first intact copper foil. The first insulation layer is disposed between the patterned layer and the first trace layer. The display module is disposed on the patterned layer. The first trace layer is disposed between the first insulation layer and the first intact copper foil, such that the first trace layer is protected by the first intact copper foil. The enveloping layer encapsulates the flexible display device.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a cross-sectional view of a card with display function according to an embodiment of the invention;

FIG. 2 shows a cross-sectional view of the flexible display device of FIG. 1;

FIG. 3 shows a cross-sectional view of the flexible display device according to other embodiment of the invention;

FIG. 4 shows a cross-sectional view of a flexible display device according to another embodiment of the invention;

FIG. 5 shows a cross-sectional view of a flexible display device according to an alternate embodiment of the invention;

FIG. 6 shows a cross-sectional view of a flexible display device according to another alternate embodiment of the invention.

### DETAILED DESCRIPTION OF THE INVENTION

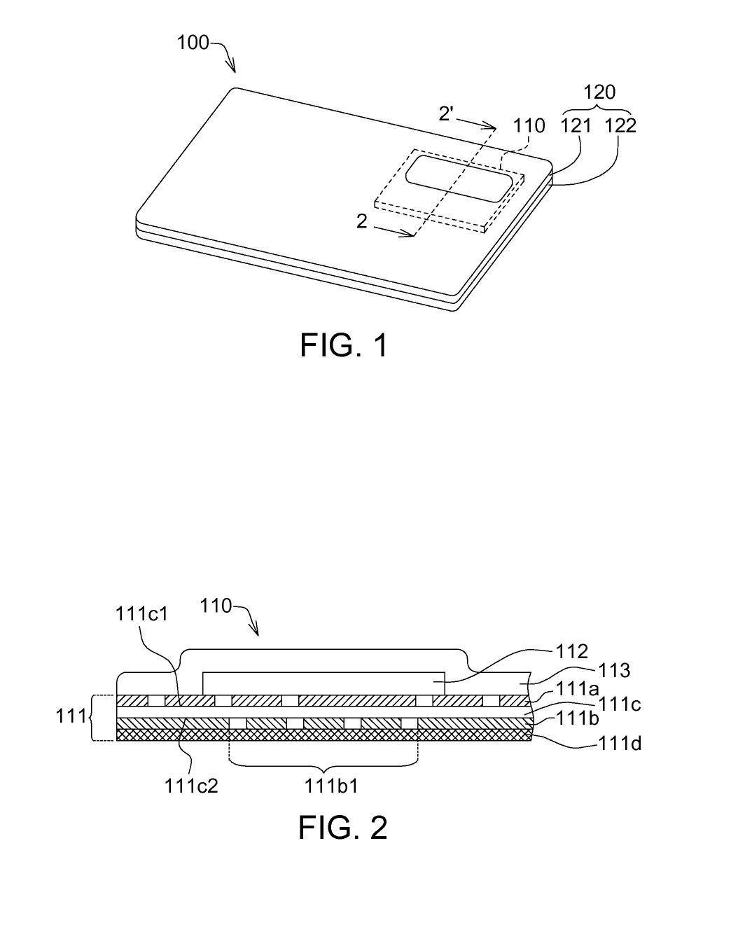

Referring to FIG. 1, a cross-sectional view of a card with display function according to an embodiment of the invention is shown. The card with display function 100 comprises a flexible display device 110 and an enveloping layer 120. The card with display function 100 may have flexibility, and can be used in such as prepaid card, password generation card, transport card, membership card, VIP card, access card, electronic key, passport, ID card, label, financial card, credit card, advertising card, entertainment card, name card, PC card, card-type computer, card-type e-book, card-type game machine or physiological signal detection card. The prepaid card is such as an electronic wallet, point card, a transport prepaid card, a telephone card or a cash card. The transport card is such as a transport prepaid card, transport par value card or ticket. The label is such as a price label or a security label.

The enveloping layer 120 encapsulates and protects the flexible display device 110. The enveloping layer 120 comprises an upper enveloping layer 121 and a lower enveloping layer 122 respectively disposed on two opposites sides of the flexible display device 110 to completely encapsulates the flexible display device 110. The enveloping layer 120 is such as a transparent enveloping layer or a partly transparent enveloping layer, so the display content can be viewed through the enveloping layer 120. Besides, the enveloping layer 120 is formed by plastics or high molecular polymer such as polyethylene terephthalate (PET) or polyvinyl chloride (PVC).

The flexible display device 110 and the enveloping layer 120 are flexible, such that the card with display function 100 can be realized as a flexible card with display function 100.

Referring to FIG. 2, a cross-sectional view of the flexible display device of FIG. 1 is shown. The flexible display device 110 comprises a multi-layer substrate 111, a display module 112 and a transparent passivation film 113. The transparent passivation film 113 encapsulates the display module 112.

The multi-layer substrate 111, such as a flexible printed circuit (FPC) and a printed circuit board (PCB), comprises at least three conductive layers to form a multi-layer structure. The first insulation layer 111c of the multi-layer substrate 111 is formed by such as FR4, FR5, polyimide (PI), polyethylene terephthalate (PET), polyvinyl chloride (PVC), PCB or glycol polyethylene naphthalate (PEN). Besides, the multi-layer substrate 111 can be realized by such as organic thin film transistors (OTFT). Moreover, the multi-layer substrate 111 can be formed by way of printing, silver colloid, carbon ink printing or circuit etching.

The multi-layer substrate 111 comprises a patterned layer 111a, a first trace layer 111b, a first insulation layer 111c and a first intact copper foil 111d. The display module 112 is disposed on the patterned layer 111a. The first insulation layer 111c is disposed between the patterned layer 111a and the first trace layer 111b. The first insulation layer 111c is disposed between the patterned layer 111a and the first trace layer 111b, and the first trace layer 111b is disposed between the first insulation layer 111c and the first intact copper foil 111d, such that the first trace layer 111b can be protected by the first intact copper foil 111d to avoid the first trace layer 111b being damaged by the atmosphere environment (such as oxidation, moisture).

With the design of the first intact copper foil 111d, the lower passivation film of the conventional flexible display device can be omitted to reduce the cost of the card with display function 100.

The first intact copper foil 111d can do without any horrowings or holes. Thus, when the first intact copper foil 111d covers the entire trace pattern 111b1 of the first trace layer 111b, the trace pattern 111b1 can not be exposed from the first intact copper foil 111d. Or, in an embodiment, the first intact copper foil 111d comprises an intact portion (not illustrated) and a patterned portion (not illustrated), wherein the intact portion does not have any horrowings or holes, but the patterned portion may be realized by a patterned structure with horrowings or holes. The intact portion of the first intact copper foil 111d covers the entire trace pattern 111b1 of the first trace layer 111b, such that the trace pattern 111b1 cannot be exposed from the first intact copper foil 111d. The patterned portion of the first intact copper foil 111d can be realized by a patterned portion without circuit function or a patterned portion not related to the display function, for example trademark.

In the present embodiment of the invention, the area of the first intact copper foil 111d is larger than or substantially equal to that of the first trace layer 111b, such that the first intact copper foil 111d may cover the entire first trace layer 111b.

The first insulation layer 111c has an upper surface 111c1 and a lower surface 111c2 opposite to the upper surface 111c1. The patterned layer 111a is formed on of the upper surface 111c1 of the first insulation layer 111c. The first trace layer 111b is formed on the lower surface 111c2 of the first insulation layer 111c and has a trace pattern 111b1. The first intact copper foil 111d at least covers the entire trace pattern 111b1 of the first trace layer 111b to avoid the atmosphere (such as the moisture) entering the trace pattern 111b1, the first trace layer 111b, the first insulation layer 111c or the display module 112.

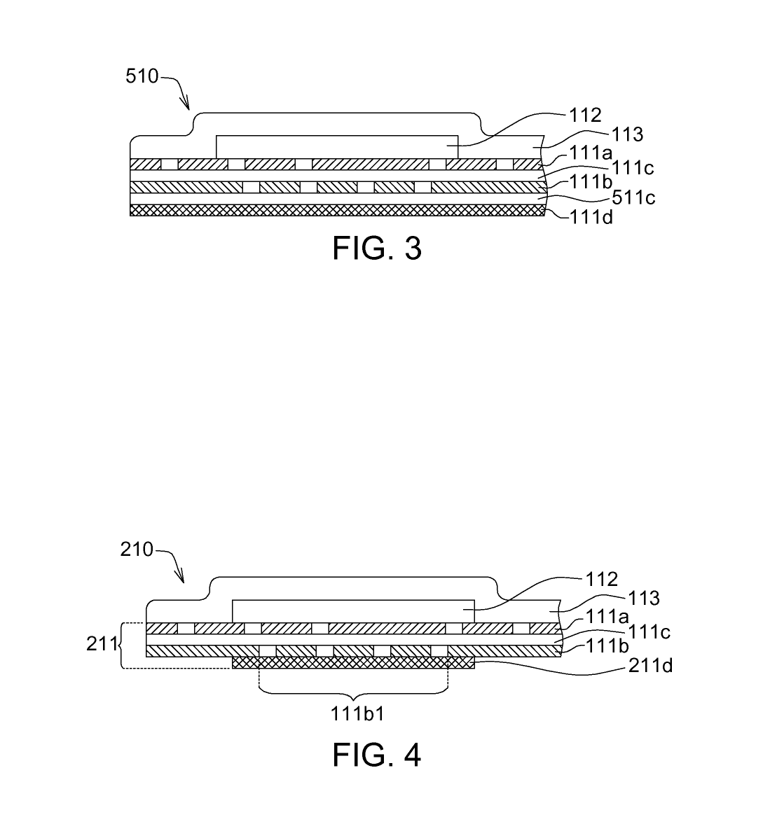

Referring to FIG. 3, a cross-sectional view of the flexible display device according to other embodiment of the invention is shown. In comparison to the flexible display device 110, the flexible display device 510 further comprises a third insulation layer 511c disposed between the first trace layer 111b and the first intact copper foil 111d for electrically isolating the first trace layer 111b and the first intact copper foil 111d.

Referring to FIG. 4, a cross-sectional view of a flexible display device according to another embodiment of the invention is shown. In the part of the flexible display device 210, the first intact copper foil 211d of the multi-layer substrate 211 does not cover the entire first trace layer 111b but covers the entire trace pattern 111b1 only to avoid the moisture entering the first trace layer 111b, the first insulation layer 111c or the display module 112 from the trace pattern 111b1. Besides, the area of the first intact copper foil 211d may be smaller than the first trace layer 111b but larger than the trace pattern 111b1, such that the first intact copper foil 211d may cover the entire trace pattern 111b1.

The display module 112 such as has bi-stability or multi-stability, such that the flexible display device 110 can permanently or temporarily maintain the display content in the absence of power supply. For example, the display module 112 is realized by such as an electrophoretic display, a cholesterol liquid crystal display, a liquid crystal display, a bi-stable display or a multi-stable display. The display module 112 can further be realized by such as a flexible organic light-emitting diode (OLED) display, a flexible light emitting diode (LED) display or a flexible liquid crystal display. Additionally, the flexible display device 410 can further be realized by segment type, dot matrix type or pattern type.

In an embodiment, despite not illustrated in the diagram, the flexible display device 210 may further comprises a third insulation layer 511c disposed between the first trace layer 111b and the first intact copper foil 211d for electrically isolating the first trace layer 111b and the first intact copper foil 211d. In the present embodiment, the area of the third insulation layer 511c is larger than or substantially equal to that of trace pattern 111b1 so as to cover the entire trace pattern 111b1. In an embodiment, the area of the third insulation layer 511c may be larger than, smaller than or substantially equal to the first intact copper foil 211d. In an embodiment, the first intact copper foil 211d may cover the entire third insulation layer 511c.

As indicated in FIGS. 2, 3 and 4, the first intact copper foil of the flexible display device may be realized by the outmost layer of the flexible display device structure. Let the flexible display device 110 be taken for example, the outmost layer structure of the flexible display device 110 is the first intact copper foil 111d, so as to effectively protect the structure between the first intact copper foil 111d and the transparent passivation film 113.

In an embodiment, the first intact copper foil 111d of the multi-layer substrate 111 does not have to be the outmost layer structure of the flexible display device 110. For example, the multi-layer substrate 111 further comprises an outmost layer structure, and the first intact copper foil 111d is disposed between the outmost layer structure and the first insulation layer 111c. The outmost layer structure is such as a patterned trace layer or an insulation passivation layer.

In short, the part between the outmost layer structure and the first trace layer of the multi-layer substrate of the invention comprises at least one intact copper foil, such that the trace layer (such as the first trace layer) disposed between the first insulation layer and the outmost layer structure of the multi-layer substrate can be protected by at least one intact copper foil. Thus, the atmosphere (such as moisture) is blocked by the intact copper foil and will not damage the trace layer between the first insulation layer and the outmost layer structure of the multi-layer substrate.

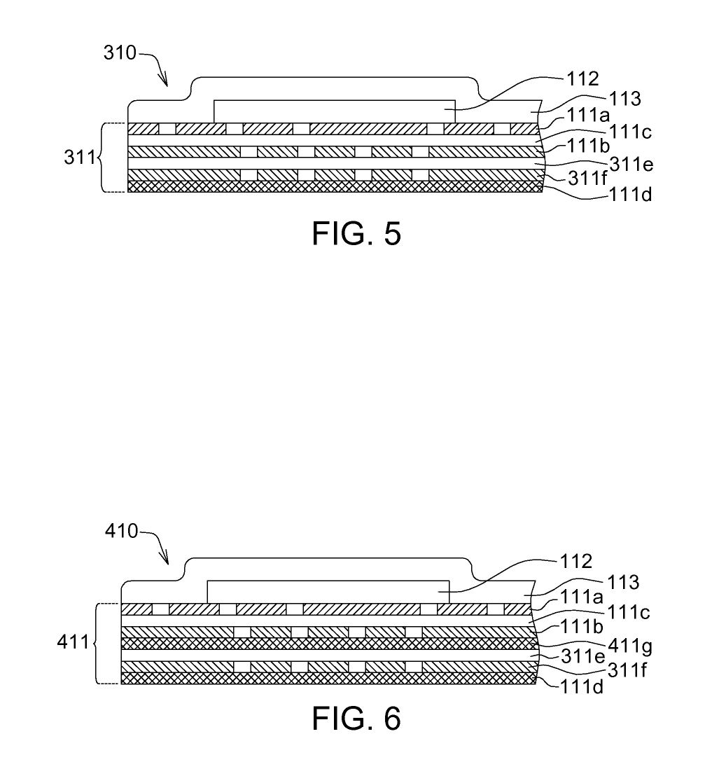

Referring to FIG. 5, a cross-sectional view of a flexible display device according to an alternate embodiment of the invention is shown. In the part of the flexible display device 310, the multi-layer substrate 311 further comprises a second insulation layer 311e and a second trace layer 311f. The second insulation layer 311e is disposed between the first trace layer 111b and the second trace layer 311f, and the second trace layer 311f is disposed between the second insulation layer 311e and the first intact copper foil 111d.

In an embodiment, despite not illustrated in the diagram, the flexible display device 310 may further comprise a third insulation layer 511c disposed between the second trace layer 311f and the first intact copper foil 111d for electrically isolating the second trace layer 311f and the first intact copper foil 111d.

In addition, the multi-layer substrate may comprise at least two intact copper foils. The design of multi-layers of intact copper foil provides multiple protection to the trace layer. According to such design, the trace layer closer to the display module (or the patterned layer) can be protected by more layers of intact copper foils.

Referring to FIG. 6, a cross-sectional view of a flexible display device according to another alternate embodiment of the invention is shown. In the part of the flexible display device 410, the multi-layer substrate 411 further comprises a second intact copper foil 411g. The second intact copper foil 411g is disposed between the second insulation layer 311e and the first trace layer 111b. In the present embodiment of the invention, the first trace layer 111b closest to the display module 112 is protected by the first intact copper foil 111d and the second intact copper foil 411g, such that the moisture can hardly damage the first trace layer 111b.

In an embodiment, despite not illustrated in the diagram, the flexible display device 410 may further comprise a third insulation layer 511c disposed between the second trace layer 311f and the first intact copper foil 111d for electrically isolating the second trace layer 311f and the first intact copper foil 111d.

According to the flexible display device and the card with display function using the same disclosed in the above embodiments of the invention, the trace layer of the substrate of the flexible display device is disposed between the insulation layer and the intact copper foil, such that the trace layer can be protected by the intact copper foil to avoid the moisture damaging the display module of the flexible display device through the substrate.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A flexible display device, comprising:
a multi-layer substrate, comprising:
a patterned layer;
a first trace layer;
a first insulation layer disposed between the patterned layer and the first trace layer; and
a first intact copper foil; and
a display module disposed on the patterned layer;
wherein, the first trace layer is disposed between the first insulation layer and the first intact copper foil, such that the first trace layer is protected by the first intact copper foil.

2. The flexible display device according to claim 1, wherein the first insulation layer has an upper surface and a lower surface opposite to the upper surface, the patterned layer is formed on the upper surface of the first insulation layer, the first trace layer is formed on the lower surface of the first insulation layer and has a trace pattern, and the first intact copper foil at least covers the entire trace pattern of the first trace layer.

3. The flexible display device according to claim 1, wherein the first intact copper foil covers the entire first trace layer.

4. The flexible display device according to claim 1, further comprising:
a passivation film encapsulating the display module.

5. The flexible display device according to claim 1, wherein the multi-layer substrate is a flexible printed circuit.

6. The flexible display device according to claim 1, wherein the first intact copper foil is the outmost layer of the flexible display device.

7. The flexible display device according to claim 1, wherein the multi-layer substrate further comprises:
a second insulation layer; and
a second trace layer;
wherein, the second insulation layer is disposed between the first trace layer and the second trace layer, and the second trace layer is disposed between the second insulation layer and the first intact copper foil.

8. The flexible display device according to claim 7, wherein the multi-layer
substrate further comprises:
a second intact copper foil disposed between the second insulation layer and the first trace layer.

9. The flexible display device according to claim 1, wherein the multi-layer substrate is a flexible printed circuit.

10. The flexible display device according to claim 1, wherein the multi-layer substrate further comprises:
a third insulation layer disposed between the first trace layer and the first intact copper foil for electrically isolating the first trace layer and the first intact copper foil.

11. A card with display function, comprising:
a flexible display device, comprising:
a multi-layer substrate, comprising:
a patterned layer;
a first trace layer;
a first insulation layer disposed between the patterned layer and the first trace layer; and
a first intact copper foil; and
a display module disposed on the patterned layer; and
an enveloping layer encapsulating the flexible display device;
wherein, the first trace layer is disposed between the first insulation layer and the first intact copper foil, such that the first trace layer is protected by the first intact copper foil.

12. The card with display function according to claim 11, wherein the first insulation layer has an upper surface and a lower surface opposite to the upper surface, the patterned layer is formed on the upper surface of the first insulation layer, the first trace layer is formed on the lower surface of the first insulation layer and has a trace pattern, and the first intact copper foil at least covers the entire trace pattern of the first trace layer.

13. The card with display function according to claim 11, wherein the first intact copper foil covers the entire first trace layer.

14. The card with display function according to claim 11, wherein the flexible display device further comprises:
a passivation film encapsulating the display module.

15. The card with display function according to claim 11, wherein the multi-layer substrate is a flexible printed circuit.

16. The card with display function according to claim 11, wherein the first intact copper foil is the outmost layer of the flexible display device.

17. The card with display function according to claim 11, wherein the multi-layer substrate further comprises:
a second insulation layer; and
a second trace layer;
wherein, the second insulation layer is disposed between the first trace layer and the second trace layer, and the second trace layer is disposed between the second insulation layer and the first intact copper foil.

18. The card with display function according to claim 17, wherein the multi-layer substrate further comprises:
a second intact copper foil disposed between the second insulation layer and the first trace layer.

19. The card with display function according to claim 11, wherein the multi-layer substrate is a flexible printed circuit.

20. The card with display function according to claim 11, wherein the multi-layer substrate further comprises:
a third insulation layer disposed between the first trace layer and the first intact copper foil for electrically isolating the first trace layer and the first intact copper foil.
